(19) United States
(12) Patent Application Publication
(10) Pub. No.: US 2011/0070710 A1
(43) Pub. Date: Mar. 24, 2011

(54) METHOD FOR FABRICATING NOR SEMICONDUCTOR MEMORY STRUCTURE

(75) Inventor: Yung-Chung Lee, Taiwan (TW)

(73) Assignee: EON SILICON SOLUTION INC., Chu-Pei City (TW)

(21) Appl. No.: 12/562,903

(22) Filed: Sep. 18, 2009

(51) Int. Cl. H01L 21/336

(52) U.S. Cl. 438/302; 257/E21.433

(57) ABSTRACT

A method for fabricating a NOR semiconductor memory structure includes: performing a deeply doped source ion implantation process and a lightly doped drain ion implantation process; forming oxide layer walls on two said sides of a gate structure, respectively; performing a pocket implant process with control of an incident angle thereof; and performing a deeply doped drain ion implantation process. Characteristics of the NOR semiconductor memory structure are improved by controllably changing the position of a pocket implant region.

### FIELD OF THE INVENTION

The present invention relates to methods for fabricating semiconductors, and more particularly, to a method for fabricating a NOR semiconductor memory structure.

### BACKGROUND OF THE INVENTION

Owing to advancement of semiconductor process technology, dimensions of metal-oxide-semiconductors (MOS) are becoming smaller, thereby reducing fabrication costs and enhancing integration of integrated circuits. However, short-channel effects (SCE) of downsized MOS brings problems, such as threshold voltage shift, and threshold voltage roll-off. Hence, it is of vital importance to design a semiconductor memory structure applicable to short-channel components.

The drawbacks of short-channel effects are usually mitigated by a double diffused drain (DDD) or a lightly doped drain (LDD) which features low doping concentration in the drain region adjacent to the gate, changeable electric field of the drain, improved characteristics of threshold voltage, reduced hot carrier effect, and decrease in current passing the substrate and the gate. However, as components of semiconductor devices are becoming smaller, punch-through has become more severe than ever before; hence, further improvement in short-channel effects is required. Prior art, for example, U.S. Pat. No. 5,917,219, entitled Semiconductor Devices with Pocket Implant and Counter Doping, disclosed a pocket implant for improving short-channel effects, including punch-through.

A pocket implant is formed by ion implantation that involves implanting ions in the vicinity of a source/drain junction so as to improve short-channel effects, such as punch-through, drain-induced barrier lowering (DIBL), and threshold voltage roll-off due to the shortening channel length. U.S. Pat. No. 5, 917,219 taught forming a pocket implant adjacent to a lightly doped drain region but has a drawback left unsolved: the pocket implant damages the junction profile of the lightly doped drain region and thereby jeopardizes metal-oxide-semiconductor field-effect transistors (MOSFET). Hence, semiconductor manufacturers are confronted with an urgent issue, further improvement in the position of the pocket implant.

### SUMMARY OF THE INVENTION

The objective of the present invention is to provide a method for fabricating a NOR semiconductor memory structure so as to protect the junction profile of the lightly doped drain region against damage by controlling the position of a pocket implant and prevent a leak current efficiently.

To achieve the above and other objectives, the present invention provides a method for fabricating a NOR semiconductor memory structure, comprising steps of: forming a gate structure on a semiconductor substrate; performing a deeply doped source ion implantation process to form a deeply doped first source region in the semiconductor substrate such that the deeply doped first source region thus formed is positioned proximate to a side of the gate structure; performing a lightly doped drain ion implantation process to form a lightly doped first drain region in the semiconductor substrate such that the lightly doped first drain region thus formed is positioned proximate to another side of the gate structure, wherein the first drain region and the first source region thus formed in the semiconductor substrate flank the gate structure; forming oxide layer walls on two said sides of the gate structure, respectively; performing a pocket implant process to form a pocket implant region in the semiconductor substrate such that the pocket implant region thus formed is positioned proximate to and beneath the lightly doped first drain region but distal to the deeply doped first source region; and performing a deeply doped drain ion implantation process to form a deeply doped second drain region in the semiconductor substrate such that the deeply doped second drain region thus formed is positioned proximate to the pocket implant region and the lightly doped first drain region but distal to the deeply doped first source region, wherein the first drain region and the second drain region overlap.

In a preferred embodiment of a method for fabricating a NOR semiconductor memory structure according to the present invention, the semiconductor substrate is a p-type semiconductor substrate.

In a preferred embodiment of a method for fabricating a NOR semiconductor memory structure according to the present invention, the pocket implant region is implanted, at an incident angle of 15 to 30 degrees, in the p-type semiconductor substrate.

### BRIEF DESCRIPTION OF THE DRAWINGS

FIG. 1 to FIG. 6 are cross-sectional views of a preferred embodiment of a semiconductor memory structure during different steps of a fabrication process thereof according to the present invention.

### DETAILED DESCRIPTION OF THE EMBODIMENT

To enable persons skilled in the art to gain insight into the objective, features, and effects of the present invention, the present invention is illustrated with the following specific embodiment and drawings. In the following specific embodiment and drawings, like components are denoted with like reference numerals.

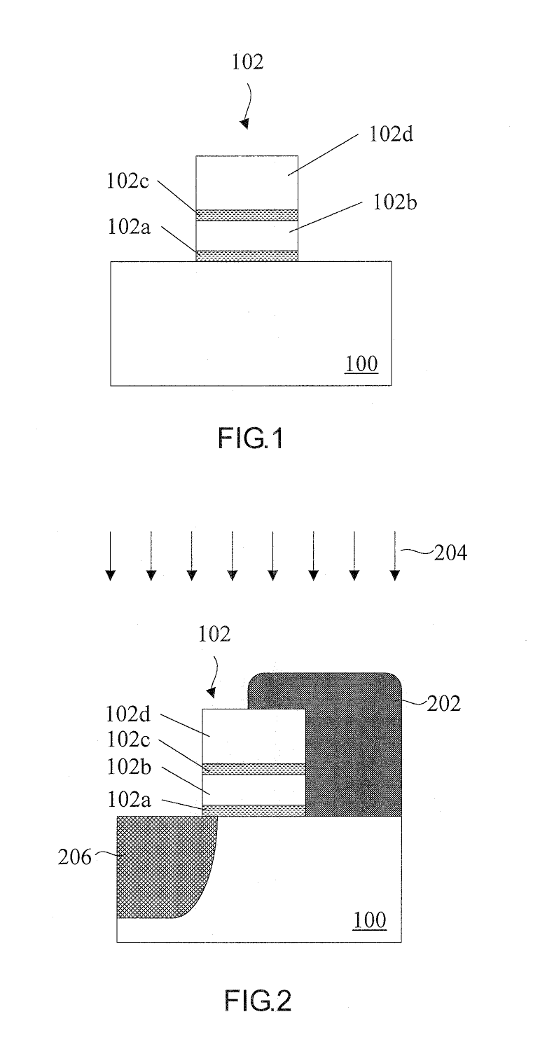

The present invention provides a method for fabricating a NOR semiconductor memory structure to improve a conventional method of performing ion implantation for a pocket implant. In a preferred embodiment of the present invention, an n-channel semiconductor memory structure has an n-type pocket implant region and an n-type source/drain region. FIG. 1 to FIG. 6 are cross-sectional views of a preferred embodiment of a semiconductor memory structure during different steps of a fabrication process thereof according to the present invention.

Referring to FIG. 1, a gate structure 102 is formed on a semiconductor substrate 100. The gate structure 102 comprises a tunnel oxide layer 102a, a floating gate 102b, a dielectric layer 102c, and a control gate 102d. The semiconductor substrate 100 can be made of silicon (Si), silicon germanium (SiGe), silicon-on-insulator (SOI), silicon-germanium-on-insulator (SGOI), and germanium-on-insulator (GOI). In this embodiment, the semiconductor substrate 100 is made of silicon, and is turned into a p-type semiconductor substrate with doped boron.

Referring to FIG. 2, a mask 202 is formed on the semiconductor substrate 100 to cover one side of the gate structure 102, and then a deeply doped source (DDS) ion implantation process 204 is performed to form a deeply doped first source region 206 in the semiconductor substrate 100 such that the deeply doped first source region 206 thus formed is positioned proximate to the other side of the gate structure 102. Take a p-type substrate as example, in the preferred embodiment of the present invention, during the DDS ion implantation process 204, 1×10¹⁴ to 8×10¹⁵ atom/cm² of arsenic ions at an energy level of 10 to 70 KeV are used.

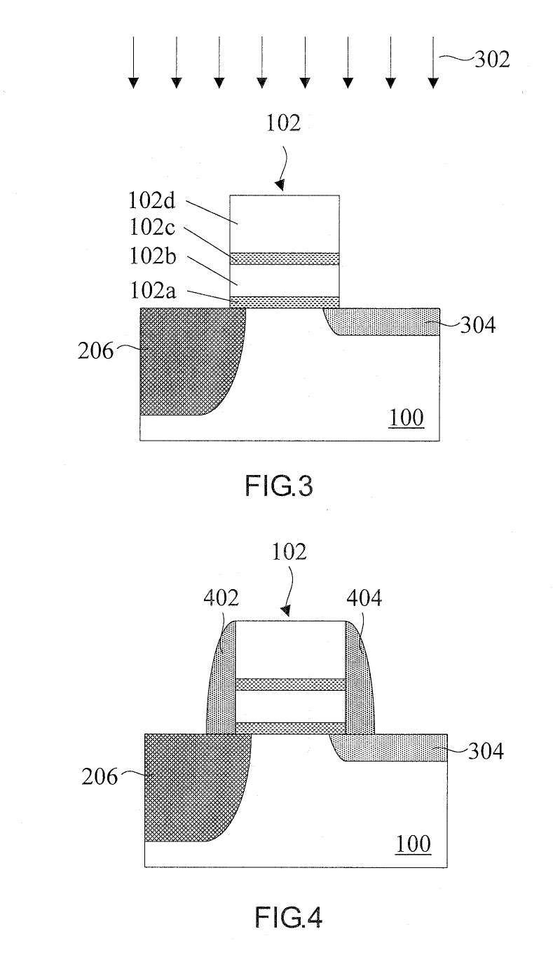

Referring to FIG. 3, a lightly doped drain (LDD) ion implantation process 302 is performed to form a lightly doped first drain region 304 in the semiconductor substrate 100 such that the lightly doped first drain region 304 thus formed is positioned proximate to said one side of the gate structure 102. The first source region 206 and the first drain region 304 thus formed in the semiconductor substrate 100 flank the gate structure 102. In the preferred embodiment, during the LDD ion implantation process 302, 1×10¹⁴ to 1×10¹⁵ atom/cm² of arsenic ions at an energy level of 10 to 30 KeV are used.

Referring to FIG. 4, oxide layer walls 402, 404 are formed on two said sides of the gate structure 102 by deposition and etching. The deposition, for example, is carried out by Chemical Vapor Deposition (CVD) using source gases including NH₃ and SiH₄, Rapid Thermal Chemical Vapor Deposition (RTCVD), or Atomic Layer Deposition (ALD). The etching is dry or wet etching.

Referring to FIG. 5, a pocket implant process 502 is performed to form a pocket implant region 504 beneath the first drain region 304. During the pocket implant process 502, the pocket implant region 504 is implanted, at an incident angle θ of 15 to 30 degrees (relative to the normal of the semiconductor substrate 100), in the semiconductor substrate 100. The pocket implant process 502 is not performed until after the oxide layer walls 402, 404 have been formed; this, coupled with the control of the incident angle used in the pocket implant process 502, allows the pocket implant region 504 to pose no harm to the junction profile of the lightly doped first drain region. In the preferred embodiment, during the pocket implant process 502, 5×10¹² to 5×10¹⁴ atom/cm² of boron (B) or boron fluoride (BF₂) ions at an energy level of 10 to 60 KeV are used.

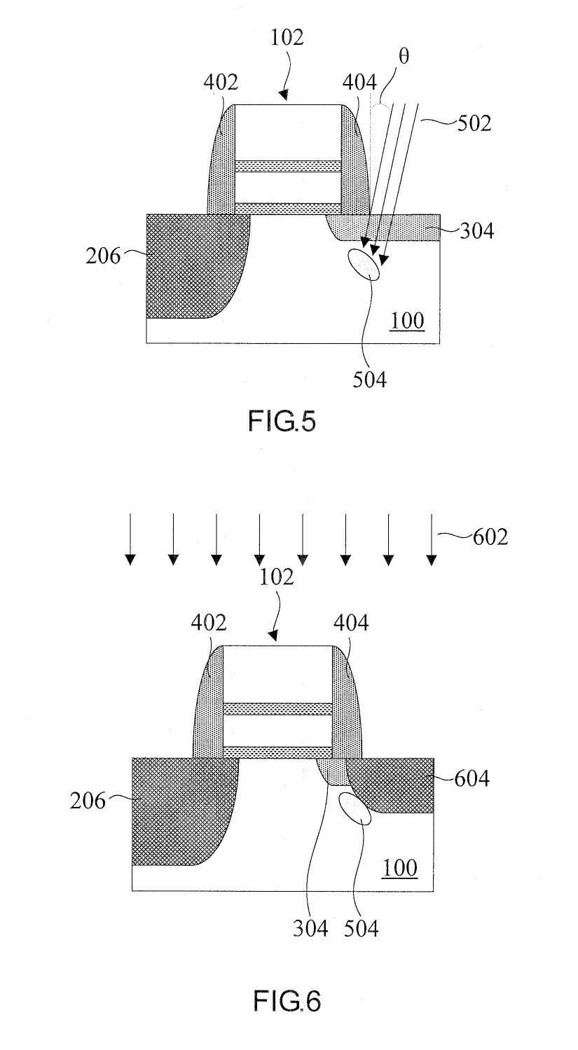

Referring to FIG. 6, a deeply doped drain (DDD) ion implantation process 602 is performed to form a deeply doped drain (DDD) second drain region 604 in the semiconductor substrate 100 such that the DDD second drain region 604 thus formed is positioned proximate to the first drain region 304 and pocket implant region 504 but distal to the deeply doped first source region 206. In the preferred embodiment, during the DDD ion implantation process 602, 1×10¹⁴ to 8×10¹⁵ atom/cm² of arsenic ions at an energy level of 10 to 70 KeV are used.

By the above fabrication process, fabrication of the NOR semiconductor memory structure of the present invention is finalized. The pocket implant region 504 poses no harm to the junction profile of the first drain region 304. Owing to its proximity to the second drain region 604, the pocket implant region 504 is effective in preventing a leak current.

A preferred embodiment of the present invention is described above. Persons skilled in the art should be able to understand that the preferred embodiment serves to illustrate part of the structure of a memory unit of the present invention rather than limits the scope of application of the present invention. It should be noted that all equivalent changes of or replacements for the preferred embodiment fall within the scope of disclosure of the present invention. Hence, the scope of protection for the present invention should be defined by the claims as found hereunder.

What is claimed is:

1. A method for fabricating a NOR semiconductor memory structure, comprising steps of:
forming a gate structure on a semiconductor substrate;
performing a deeply doped source ion implantation process to form a deeply doped first source region in the semiconductor substrate such that the deeply doped first source region thus formed is positioned proximate to a side of the gate structure;
performing a lightly doped drain ion implantation process to form a lightly doped first drain region in the semiconductor substrate such that the lightly doped first drain region thus formed is positioned proximate to another side of the gate structure, wherein the first drain region and the first source region thus formed in the semiconductor substrate flank the gate structure;
forming oxide layer walls on two said sides of the gate structure, respectively;
performing a pocket implant process to form a pocket implant region in the semiconductor substrate such that the pocket implant region thus formed is positioned proximate to and beneath the lightly doped first drain region but distal to the deeply doped first source region; and
performing a deeply doped drain ion implantation process to form a deeply doped second drain region in the semiconductor substrate such that the deeply doped second drain region thus formed is positioned proximate to the pocket implant region and the lightly doped first drain region but distal to the deeply doped first source region, wherein the first drain region and the second drain region overlap.

2. The method of claim 1, wherein the semiconductor substrate is a p-type semiconductor substrate.

3. The method of claim 1, wherein the pocket implant region is implanted, at an incident angle of 15 to 30 degrees, in the semiconductor substrate.

4. The method of claim 3, wherein boron or boron fluoride ions are used in the pocket implant process.

5. The method of claim 4, wherein during the pocket implant process 5×10¹² to 5×10¹⁴ atom/cm² of ions at an energy level of 10 to 60 KeV are used.
